(19) United States
(12) Patent Application Publication
(10) Pub. No.: US 2026/0206261 A1
(43) Pub. Date: Jul. 16, 2026

(54) Process and structure of ferroelectric neural network cell with self-learning capability and enhanced character recognition length

(71) Applicant: National Central University, Taoyuan City (TW)

(72) Inventors: Ying-Tsan Tang, Taoyuan City (TW); Zi-Rong Huang, Taoyuan City (TW); Hao-Ming Chen, Taoyuan City (TW); Sheng-Tsang Huang, Taoyuan City (TW)

(21) Appl. No.: 19/199,565

(22) Filed: May 6, 2025

(30) Foreign Application Priority Data
Jan. 15, 2025 (TW) 114101643

(51) Int. Cl. H10D 30/69; G06N 3/063; H10B 51/30; H10D 30/01; H10D 64/01; H10D 64/66; H10D 64/68

(52) U.S. Cl. CPC H10D 30/701; G06N 3/063; H10B 51/30; H10D 30/0415; H10D 64/033; H10D 64/666; H10D 64/669; H10D 64/689

(57) ABSTRACT

The present invention is a process and structure of a ferroelectric neural network cell with self-learning capability and enhanced character recognition length. The ferroelectric neural network cell is a content addressable memory (CAM) structure (or FeCAM for short) based on a ferroelectric field-effect transistor (FeFET), and the FeCAM is a 1N1P-FeCAM including an N-type FeFET and a P-type FeFET. Therefore, the present invention reduces the number of devices to minimize cell area, and each cell consists of two complementary FeFETs to achieve a density that is 33% higher than that of Ternary CAM (TCAM). H₂ plasma treatment (HPT) is effective in enhancing symmetry between I_{ON1} and I_{ON2} to increase the number of mismatch cells (Max HD, MHD). Therefore, the present invention is useful to graphic recognition and can be applied to various fields of artificial intelligence.

### FIELD OF THE INVENTION

The present invention relates to a ferroelectric neural network cell with self-learning capability and enhanced character recognition length and a structure of the same. More particularly, the present invention relates to a 1N1P-based FeCAM. Much more particularly, the present invention relates to enhancing symmetry between I_{ON1} and I_{ON2} and increasing the number of mismatch cells (Max HD, MHD) through H₂ plasma treatment (HPT).

### DESCRIPTION OF THE PRIOR ART

Content addressable memory (CAM) leverages many memory technologies for parallel pattern matching and distance computations. Ferroelectric field-effect transistor (FeFET) stands out due to its single-transistor structure, non-volatility, and energy efficiency. FeFET-based CAM (or FeCAM for short) designs enhance data density through multi-level cell (MLC) implementations or reduced device count strategies. A classical 2FeFET CAM improves density 8× compared to SRAM-based design. Despite the fascinating FeFET design, asymmetry in current due to carrier mobility differences, contact resistance, and parasitic capacitance may introduce fluctuations in match current, thereby limiting the number of mismatched cells i.e., Hamming distances (HD).

Therefore, from operation and application perspectives, conventional FeCAM is confronted by issues as follows:

Limitation on the number of instances of writing: one of the characteristics of FeFET is its ferroelectric properties, but the number of instances of writing of ferroelectric materials is limited. Lengthy and frequent writing operations may cause degradation of ferroelectric materials and thus place a limitation on the service life and reliability of devices.

Temperature stability: the performance of fecam depends on temperature variations; in particular, variations in extreme temperatures may cause instability in FeCAM characteristics, necessitating additional compensatory measures to ensure stable operation.

In view of this, it is essential to develop an invention that addresses the challenges faced by conventional FeCAM and overcomes the aforementioned drawbacks of prior art.

### BRIEF SUMMARY OF THE INVENTION

Therefore, the main purpose of the present invention is to overcome the aforementioned drawbacks of prior art and provide a ferroelectric neural network cell process and structure, characterized by a 1N1P-FeCAM comprising 1N-type FeFET (N-type FeFET) and 1P-type FeFET (P-type FeFET), and comparing the 1N1P-FeCAM with a sample that has undergone H₂ plasma treatment (HPT). The comparison result shows that the treated 1N1P-FeCAM has less trap charges and thus features enhanced symmetry between I_{ON1} and I_{ON2}, increasing the number of mismatch cells.

Another purpose of the present invention is to overcome the aforementioned drawbacks of prior art and provide a ferroelectric neural network cell process and structure, characterized in that the structure can be used in artificial intelligence image recognition such that FeCAM cells use different threshold voltages (Vth) to store their image features to achieve pattern similarity recognition.

To achieve the above purposes, the present invention is a method of making a ferroelectric neural network cell, involving an N-type FeFET process, that at least comprises the steps of: rinsing a first silicon substrate; performing atomic layer deposition (ALD) on the first silicon substrate to grow an interfacial layer (IL); performing the ALD on the interfacial layer to stack an angstrom-level layer of hafnium dioxide/zirconium dioxide (HfO₂/ZrO₂) to form a first hafnium-zirconium oxide (HZO) structure; performing physical vapor deposition (PVD) on the first HZO structure to deposit a first titanium nitride (TiN) layer to form a first metal oxide semiconductor field effect transistor (MOSFET) structure; etching and patterning the first silicon substrate, the interfacial layer, the first HZO structure, and the first TiN layer to form a first source/drain region (S/D), doping the first source/drain region with a P-dopant, followed by performing an annealing process to activate the dopant in the first source/drain region to obtain an N-type FeFET; and performing H₂ plasma treatment (HPT) on the N-type FeFET, followed by introducing H₂ into the N-type FeFET at 20 sccm±20% for 400 seconds±20% when radio frequency power falls within 100 W±20%.

In the embodiment of the present invention, the method of making a ferroelectric neural network cell further comprises a P-type FeFET process that at least comprises the steps of: rinsing a second silicon substrate; performing ALD on the second silicon substrate to stack an angstrom-level layer of HfO₂/ZrO₂ to form a second HZO structure; performing PVD on the second HZO structure to sequentially deposit a second TiN layer, a molybdenum (Mo) layer, and a third TiN layer to form a second MOSFET structure; and etching and patterning the second silicon substrate, the second HZO structure, the second TiN layer, the molybdenum layer, and the third TiN layer to form a second source/drain region, doping the second source/drain region with a B-dopant, followed by performing an annealing process to activate dopants in the second source/drain region to obtain a P-type FeFET.

In the embodiment of the present invention, the first or second silicon substrate is rinsed by an RCA Clean standard process.

In the embodiment of the present invention, the interfacial layer is aluminum oxide (AlOx) with a thickness of 1 nm±20%.

In the embodiment of the present invention, the first or second HZO structure has a thickness of 9 nm±20% formed by cyclically stacking HfO₂ and ZrO₂ each having a thickness of 7 Å in every cycle of the ALD.

In the embodiment of the present invention, the first TiN layer has a thickness of 50 nm±20%.

In the embodiment of the present invention, the second TiN layer has a thickness of 2.5 nm±20%, the molybdenum layer has a thickness of 30 nm±20%, and the third TiN layer has a thickness of 50 nm±20%.

In the embodiment of the present invention, the first or second source/drain region is a doped region in the first or second silicon substrate.

In the embodiment of the present invention, the annealing process comprises annealing the first or second source/drain region on the first or second silicon substrate at 900° C.±20% for 5 seconds±20% to activate the P-type dopant or the B-dopant in the first or second source/drain region.

To achieve the above purposes, the present invention is a ferroelectric neural network cell, comprising: an N-type FeFET comprising: a first silicon substrate; a first gate stack disposed above the first silicon substrate and comprising an interfacial layer, a first HZO structure disposed above the interfacial layer, and a first TiN layer disposed above the first HZO structure; and a first source/drain region located proximate to each of two sides of the first gate stack, wherein the N-type FeFET is a FeFET having undergone H₂ plasma treatment (HPT); and a P-type FeFET comprising: a second silicon substrate; a second gate stack disposed above the second silicon substrate and comprising a second HZO structure, a second TiN layer disposed above the second HZO structure, a molybdenum layer disposed above the second TiN layer, and a third TiN layer disposed above the molybdenum layer; and a second source/drain region located proximate to each of two sides of the second gate stack, wherein source regions of the N-type FeFET and the P-type FeFET are coupled to a matching line (ML), and drain regions of the N-type FeFET and the P-type FeFET are coupled to a ground end.

In the embodiment of the present invention, the interfacial layer is aluminum oxide with a thickness of 1 nm±20%.

In the embodiment of the present invention, the first and second HZO structures are formed to take on a total thickness of 9 nm±20% by cyclically stacking 7 Å HfO₂ and 7 Å ZrO₂.

In the embodiment of the present invention, the first TiN layer has a thickness of 50 nm±20%, the second TiN layer has a thickness of 2.5 nm±20%, the molybdenum layer has a thickness of 30 nm±20%, and the third TiN layer has a thickness of 50 nm±20%.

In the embodiment of the present invention, the first source/drain region is a P-type doped region in the first silicon substrate, and the second source/drain region is a B-type doped region in the second silicon substrate.

### BRIEF DESCRIPTION OF THE DRAWINGS

FIG. 1 is a schematic view of the structure of an N-type FeFET of the present invention.

FIG. 2 illustrates a cross-section TEM image taken of the N-type FeFET of the present invention.

FIG. 3 is a schematic view of the structure of a P-type FeFET of the present invention.

FIG. 4 is a schematic view of a circuit of a 1N1P-FeCAM of the present invention.

FIG. 5 is a schematic view of a process flow of making the N-type FeFET of the present invention.

FIG. 6 is a schematic view of a process flow of making the P-type FeFET of the present invention.

FIG. 7 is a graph showing the I_{D}-V_{G} curves illustrative of the N-type FeFET and the P-type FeFET used in a FeCAM model of the present invention.

FIG. 8 is a graph showing the curves illustrative of multiple matching windows formed at different positions through different bias pulses according to the present invention.

FIG. 9 is a graph showing the I_{ML}-V_{SL} curves illustrative of different states written to two 1N1P-FeCAM cells respectively according to the present invention.

FIG. 10 is a graph showing the I_{ML}-V_{SL} curves before the 1N1P FeCAM undergoes H₂ plasma treatment (HPT) according to the present invention.

FIG. 11 is a graph showing the I_{ML}-V_{SL} curves after the 1N1P FeCAM has undergone H₂ plasma treatment (HPT) according to the present invention.

FIG. 12 is a graph showing the I_{ML}-V_{SL} curves at different temperatures before the 1N1P FeCAM undergoes H₂ plasma treatment (HPT) according to the present invention.

FIG. 13 is a graph showing the I_{ML}-V_{SL} curves at different temperatures after the 1N1P FeCAM has undergone H₂ plasma treatment (HPT) according to the present invention.

FIG. 14 is a schematic view of a neural network comprising 1T-1FeFET cells according to the present invention.

FIG. 15 is a comparison table of the present invention and different technologies

### DESCRIPTION OF THE PREFERRED EMBODIMENTS

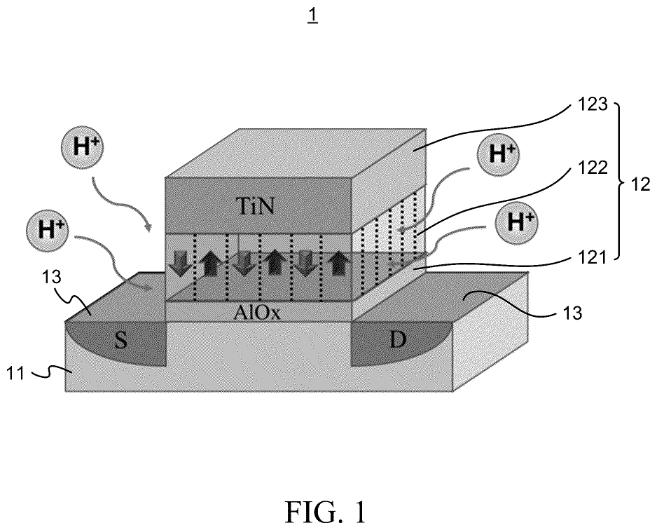

Please refer to FIG. 1 through FIG. 14, which are a schematic view of an N-type FeFET of the present invention, a cross-section TEM image taken of the N-type FeFET, a schematic view of a P-type FeFET of the present invention, a schematic view of a circuit of a 1N1P-FeCAM of the present invention, a schematic view of a process flow of making the N-type FeFET, a schematic view of a process flow of making the P-type FeFET, a graph showing the ID-VG curves illustrative of the N-type FeFET and the P-type FeFET used in a FeCAM model according to the present invention, a graph showing the curves illustrative of multiple matching windows formed at different positions through different bias pulses according to the present invention, a graph showing the I_{ML}-V_{SL} curves illustrative of different states written to two 1N1P-FeCAM cells respectively, a graph showing the I_{ML}-V_{SL} curves before the 1N1P FeCAM undergoes H2 plasma treatment (HPT), a graph showing the I_{ML}-V_{SL} curves after the 1N1P FeCAM has undergone H2 plasma treatment (HPT), a graph showing the I_{ML}-V_{SL} curves at different temperatures before the 1N1P FeCAM undergoes H2 plasma treatment (HPT), a graph showing the I_{ML}-V_{SL} curves at different temperatures after the 1N1P FeCAM has undergone H2 plasma treatment (HPT), and a schematic view of a neural network comprising 1T-1FeFET cells according to the present invention. As shown in the diagrams, the present invention is a process and structure of a ferroelectric neural network cell with self-learning capability and enhanced character recognition length. The ferroelectric neural network cell is a content addressable memory (CAM) structure (or FeCAM for short) based on a ferroelectric field-effect transistor (FeFET), and the FeCAM is a 1N1P-FeCAM comprising an N-type FeFET 1 and a P-type FeFET 2.

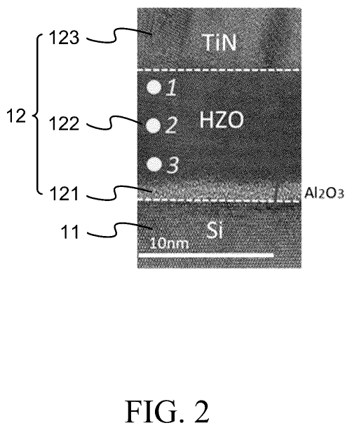

The structure of the N-type FeFET 1 is shown in FIG. 1. A cross-section transmission electron microscope (TEM) image is shown in FIG. 2. The N-type FeFET 1 is a FeFET that has undergone H₂ plasma treatment (HPT) and comprises: a first silicon substrate 11; a first gate stack 12 disposed above the first silicon substrate 11, wherein the first gate stack 12 comprises an interfacial layer (IL) 121, a first hafnium-zirconium oxide (HZO) structure 122 disposed above the interfacial layer 121, and a first titanium nitride (TiN) layer 123 disposed above the first HZO structure 122; and a first source/drain region (S/D) 13 located proximate to each of two sides of the first gate stack 12.

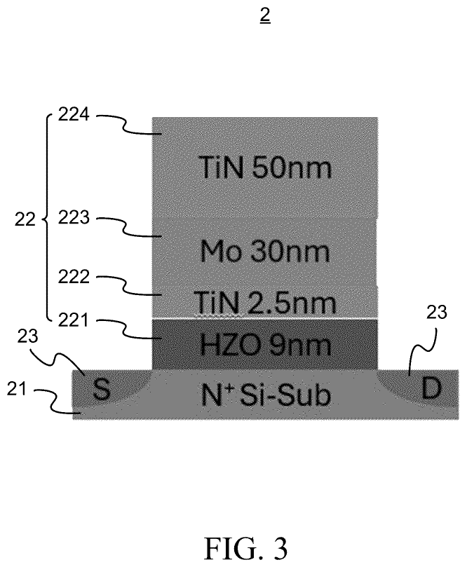

The structure of the P-type FeFET 2 is shown in FIG. 3. The P-type FeFET 2 comprises: a second silicon substrate 21; a second gate stack 22 disposed above the second silicon substrate 21, wherein the second gate stack 22 comprises a second HZO structure 221, a second TiN layer 222 disposed above the second HZO structure 221, a molybdenum (Mo) layer 223 disposed above the second TiN layer 222, and a third TiN layer 224 disposed above the molybdenum layer 223; and a second source/drain region 23 located proximate to each of two sides of the second gate stack 22.

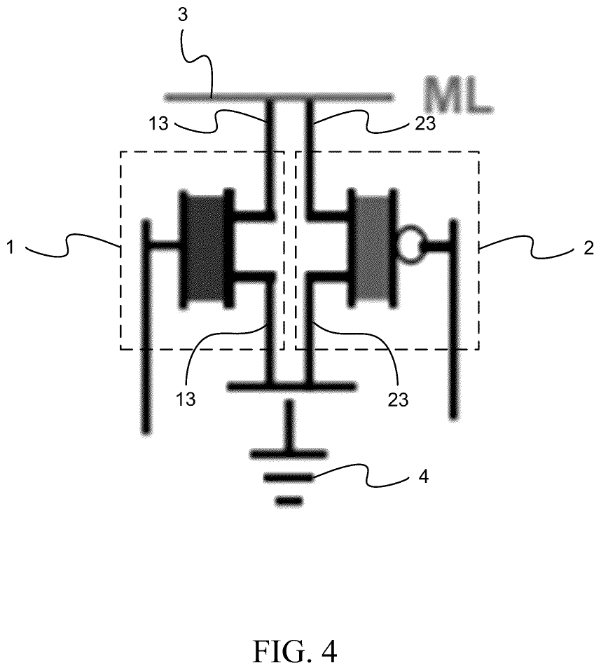

A schematic view of a circuit of a 1N1P-FeCAM of the present invention is shown in FIG. 4. Source regions 13, 23 of the N-type FeFET 1 and the P-type FeFET 2 are coupled to a matching line (ML) 3. Drain regions 13, 23 of the N-type FeFET 1 and the P-type FeFET 2 are coupled to a ground end 4.

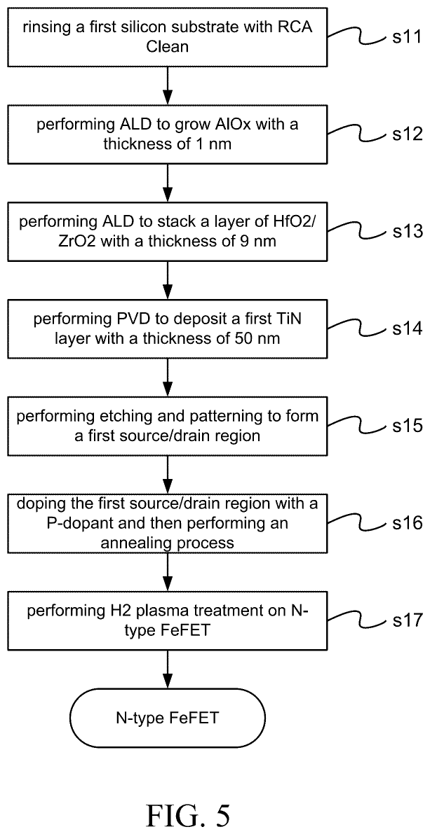

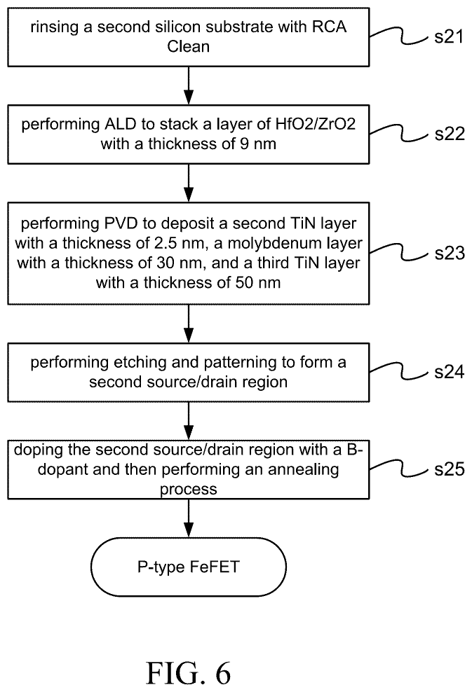

A process flow of making the N-type FeFET 1 is shown in FIG. 5. Step s11 involves rinsing the first silicon substrate 11 with RCA Clean. Step s12 involves performing atomic layer deposition (ALD) on the first silicon substrate 11 to grow an interfacial layer 121 comprising aluminum oxide (AlOx) and having a thickness of 1 nm. Step s13 involves cyclically stacking on the interfacial layer 121 hafnium dioxide (HfO₂) and zirconium dioxide (ZrO₂) each having a thickness of 7 Å in every cycle of the ALD to form the first HZO structure 122 with a thickness of 9 nm. Step s14 involves performing physical vapor deposition (PVD) on the first HZO structure 122 to deposit the first TiN layer 123 with a thickness of 50 nm so as to form a first metal oxide semiconductor field effect transistor (MOSFET) structure. Step s15 involves performing etching and patterning on the first silicon substrate 11, the interfacial layer 121, the first HZO structure 122, and the first TiN layer 123 to form the first source/drain region 13. Step s16 involves doping the first source/drain region 13 with a P-dopant and then performing an annealing process at 900° C. for 5 seconds to activate the P-dopant in the first source/drain region 13. Finally, step s17 involves performing H₂ plasma treatment (HPT) on the N-type FeFET 1 thus obtained and then introducing H₂ into the N-type FeFET at 20 sccm for 400 seconds with radio frequency power of 100 W. A process flow of making the P-type FeFET 2 is illustrated by FIG. 6. In step s21, the second silicon substrate 21 is cleaned with RCA Clean. In step s22, the ALD is performed on the second silicon substrate 21 to form the second HZO structure 221 with a thickness of 9 nm by cyclically stacking HfO₂ and ZrO₂ each having a thickness of 7 Å in every cycle of the ALD. In step s23, the PVD is performed on the second HZO structure 221 to sequentially deposit the second TiN layer 222 with a thickness of 2.5 nm, the molybdenum layer 223 with a thickness of 30 nm, and the third TiN layer 224 with a thickness of 50 nm to form a second MOSFET structure. Step s24 involves performing etching and patterning on the second silicon substrate 21, the second HZO structure 221, the second TiN layer 222, the molybdenum layer 223, and the third TiN layer 224 to form the second source/drain region 23. Step s25 involves doping the second source/drain region 23 with a B-dopant and then performing an annealing process at 900° C. for 5 seconds to activate the dopant in the second source/drain region 23 to obtain a P-type FeFET 2.

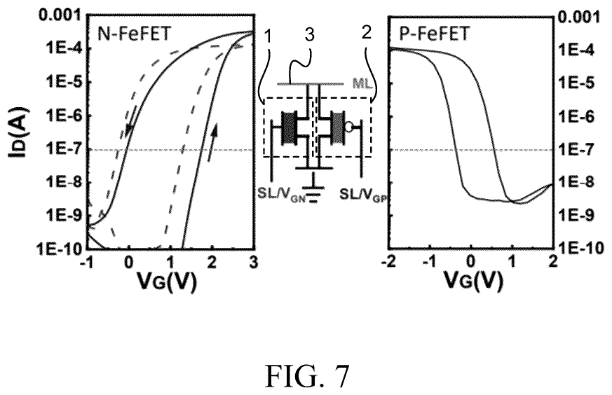

Referring to FIG. 7, a circuit diagram of a FeCAM model used in this embodiment is shown in the middle, and I_{D}-V_{G} curves illustrative of the N-type FeFET 1 used in the FeCAM model in this embodiment are shown in the left, with dashed lines indicating that the N-type FeFET 1 has not undergone H₂ plasma treatment (HPT), and solid lines indicating that the N-type FeFET 1 has undergone H₂ plasma treatment (HPT). The I_{D}-V_{G} curves illustrative of the P-type FeFET 2 used in the FeCAM model in this embodiment are shown on the right of FIG. 7. As demonstrated by the findings, after using HPT, the I_{ON}/I_{OFF} ratio reaches 8 orders of magnitude.

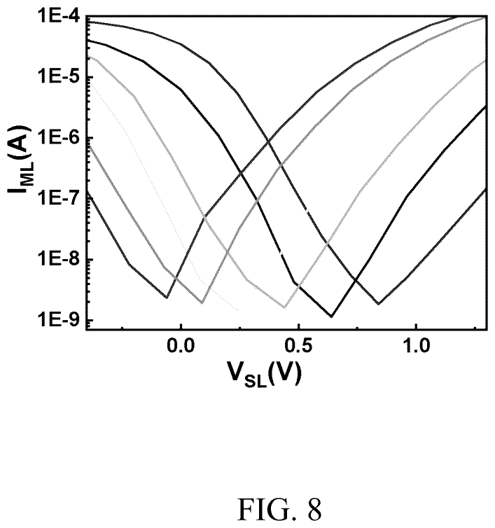

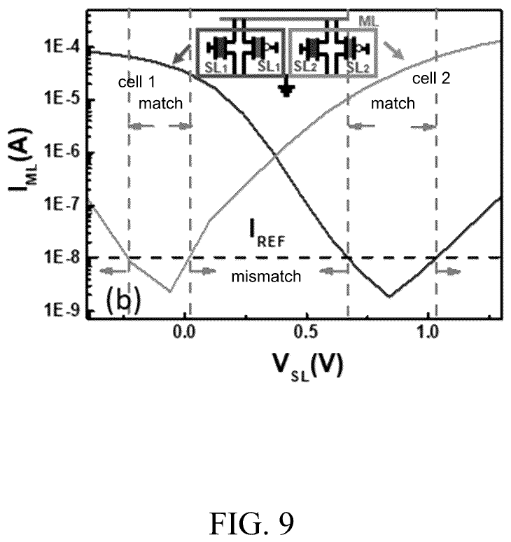

FIG. 8 illustrates the measured electrical performance of the 1N1P-FeCAM, including six different matching windows obtained through applying different pulses to change the positions of the matching windows. FIG. 9 is a graph showing the I_{ML}-V_{SL} curves illustrative of different states written to two 1N1P-FeCAM cells respectively, wherein a match is indicated if I_{ML}<I_{REF}, otherwise a mismatch is indicated.

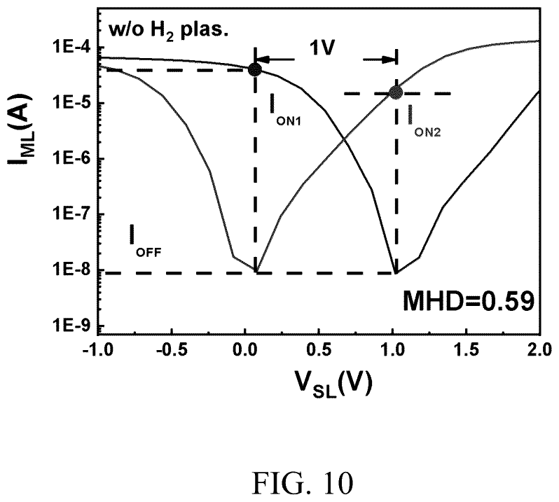

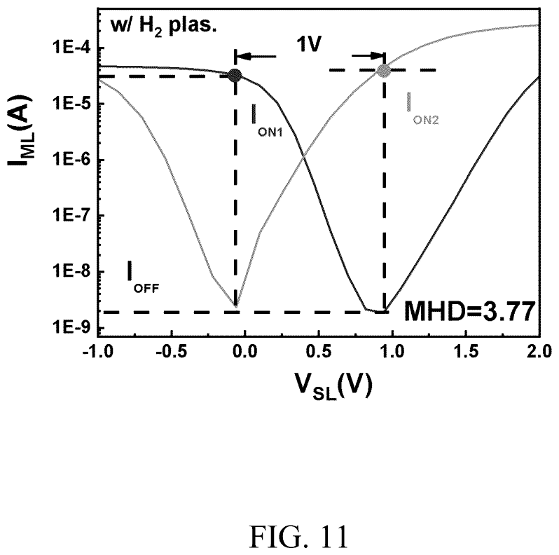

FIGS. 10 and 11 show measurement results (memory window (MW)=1V) obtained at different temperatures, using the curves I_{ML}-V_{SL} before and after H₂ plasma treatment (HPT). The curves I_{ML}-V_{SL} of the FeCAM before and after H₂ plasma treatment (HPT) demonstrate enhanced symmetry between I_{ON1} and I_{ON2} upon completion of defect repair, resulting in an increase in the number of mismatch cells (Max HD, MHD) according to the equation MHD=(I_{ON1}−I_{OFF})/(I_{ON2}−I_{ON1}).

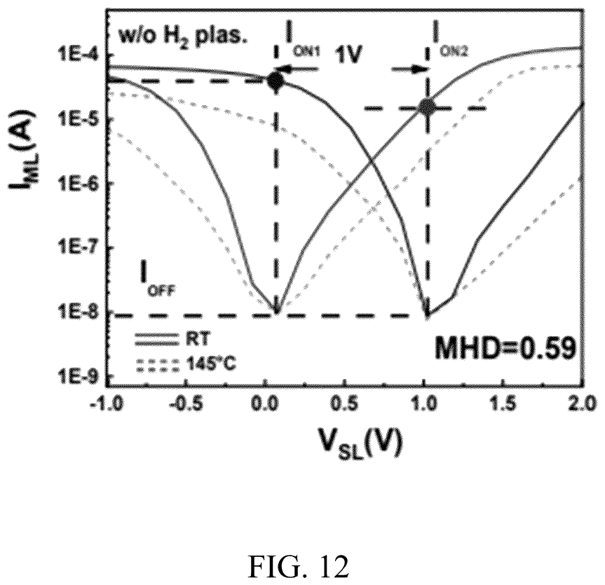

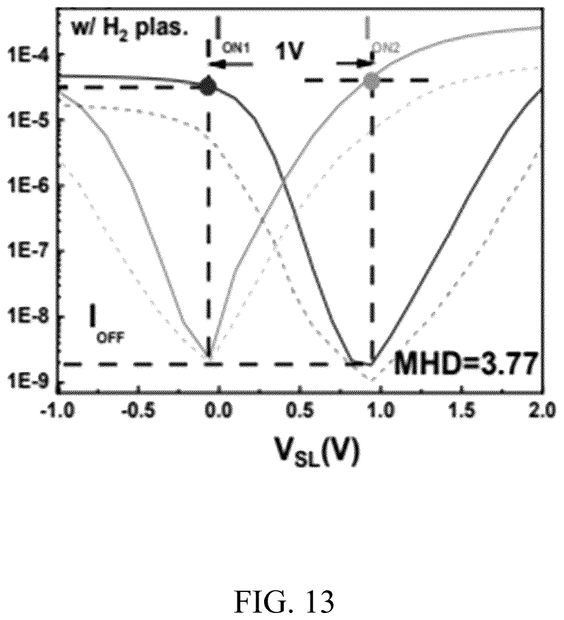

Referring to FIGS. 12 and 13, given a room temperature (25° C.) and 145° C., the asymmetry between I_{ON1} and I_{ON2} increases with temperature, which can be attributed to N/P MOS mobility differences. By contrast, the FeCAM that has undergone H₂ plasma treatment (HPT) demonstrates better heat resistance and reduced variability.

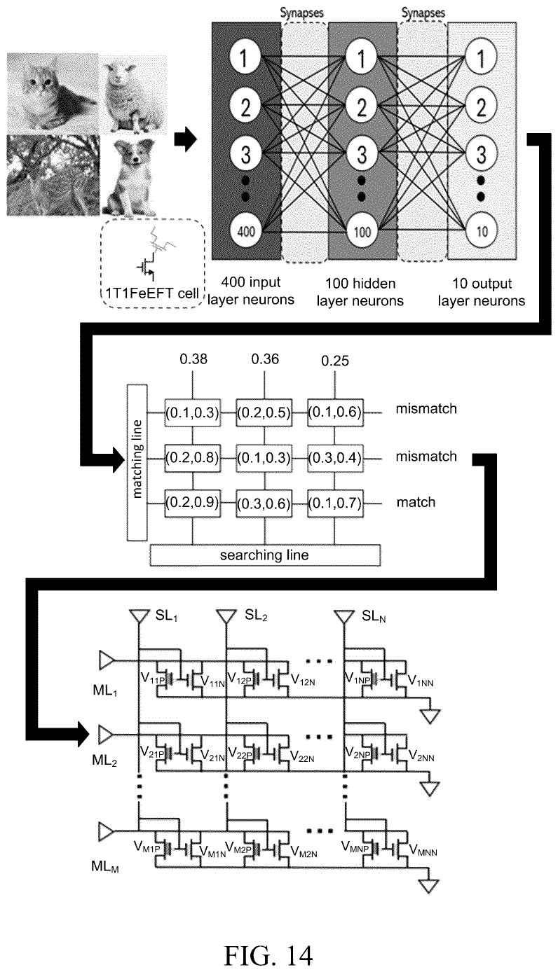

As shown in FIG. 14, different animal patterns (cats, sheep, deer, and dogs) are trained such that FeCAM cells use different threshold voltages (Vth) to store their animal features to achieve pattern similarity recognition.

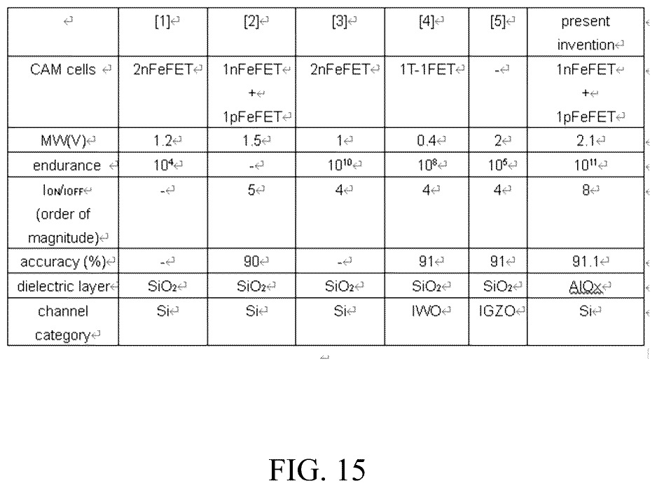

As shown in FIG. 15 the structure of the present invention is 1N1P-FeCAM instead of 2N-FeCAM, with MW of 2.1 V, and the Iₒₙ/I_{off} ratio reaches 8 orders of magnitude, with endurance of 10¹¹ cycles, and accuracy of 91.1%.

The present invention is characterized by a 1N1P-FeCAM comprising a 1N-type FeFET and a 1P-type FeFET and comparing the 1N1P-FeCAM with a sample that has undergone H2 plasma treatment (HPT). The comparison result shows that the treated 1N1P-FeCAM has less trap charges and thus features enhanced symmetry between I_{ON1} and I_{ON2}, increasing the number of mismatch cells. Therefore, from an application perspective, the present invention is applicable to artificial intelligence image recognition such that FeCAM cells use different threshold voltages (Vth) to store their image features to achieve pattern similarity recognition.

Regarding novelty, the present invention can be distinguished from conventional ternary content addressable memory (TCAM) and 2N-FeCAM. The structure of the present invention is formed from a 1N1P framework and can be applied to various fields of artificial intelligence.

Regarding non-obviousness, the present invention can be distinguished from conventional TCAM and 2N-FeCAM. The structure of the present invention is formed from a 1N1P framework and can reduce the number of devices to minimize cell area (when compared with static random-access memory (SRAM)). A classical 2FeFET CAM improves density 8× compared to SRAM-based design, each cell consists of two complementary FeFETs and thus is expected to achieve a density 33% higher than that of TCAM. H₂ plasma treatment (HPT) is effective in enhancing symmetry between I_{ON1} and I_{ON2}, increasing the number of mismatch cells. Therefore, the present invention is useful to graphic recognition and can be applied to various fields of artificial intelligence.

In conclusion, the present invention is a process and structure of a ferroelectric neural network cell with self-learning capability and enhanced character recognition length and is effective in overcoming various drawbacks of prior art. The structure is formed from a 1N1P framework and thus reduces the number of devices to minimize cell area. Each cell consists of two complementary FeFETs to achieve a density 33% higher than that of TCAM. H₂ plasma treatment (HPT) is effective in enhancing symmetry between I_{ON1} and I_{ON2} to increase the number of mismatch cells. The present invention is useful to graphic recognition and can be applied to various fields of artificial intelligence. The present invention is not only novel and practical but also meets user needs, thereby fulfilling the requirements for patentability.

The preferred embodiments herein disclosed are not intended to unnecessarily limit the scope of the invention. Therefore, simple modifications or variations belonging to the equivalent of the scope of the claims and the instructions disclosed herein for a patent are all within the scope of the present invention.

What is claimed is:

1. A method of making a ferroelectric neural network cell, the method comprising an N-type FeFET process, the N-type FeFET process at least comprising the steps of:
rinsing a first silicon substrate;
performing atomic layer deposition (ALD) on the first silicon substrate to grow an interfacial layer (IL);
performing the ALD on the interfacial layer to stack an angstrom-level layer of hafnium dioxide/zirconium dioxide (HfO₂/ZrO₂) to form a first hafnium-zirconium oxide (HZO) structure;
performing physical vapor deposition (PVD) on the first HZO structure to deposit a first titanium nitride (TiN) layer so as to form a first metal oxide semiconductor field effect transistor (MOSFET) structure;
etching and patterning the first silicon substrate, the interfacial layer, the first HZO structure, and the first TiN layer to form a first source/drain region (S/D), doping the first source/drain region with a P-dopant, followed by performing an annealing process to activate the dopant in the first source/drain region to obtain an N-type FeFET; and
performing H₂ plasma treatment (HPT) on the N-type FeFET, followed by introducing H₂ into the N-type FeFET at 20 sccm±20% for 400 seconds±20% when radio frequency power falls within 100 W±20%.

2. The method of claim 1, further comprising a P-type FeFET process, the P-type FeFET process at least comprising the steps of:
rinsing a second silicon substrate;
performing the ALD on the second silicon substrate to stack an angstrom-level layer of hafnium dioxide/zirconium dioxide (HfO₂/ZrO₂) to form a second HZO structure;
performing the PVD on the second HZO structure to sequentially deposit a second TiN layer, a molybdenum (Mo) layer, and a third TiN layer to form a second MOSFET structure; and
performing etching and patterning on the second silicon substrate, the second HZO structure, the second TiN layer, the molybdenum layer, and the third TiN layer to form a second source/drain region, doping the second source/drain region with a B-dopant, followed by performing an annealing process to activate the dopant in the second source/drain region to obtain a P-type FeFET.

3. The method of claim 1, wherein the first or second silicon substrate is rinsed by an RCA Clean standard process.

4. The method of claim 1, wherein the interfacial layer is aluminum oxide (AlOx) with a thickness of 1 nm±20%.

5. The method of claim 1, wherein the first or second HZO structure has a thickness of 9 nm±20% formed by cyclically stacking HfO₂ and ZrO₂ each having a thickness of 7 Å in every cycle of the ALD.

6. The method of claim 1, wherein the first TiN layer has a thickness of 50 nm±20%.

7. The method of claim 2, wherein the second TiN layer has a thickness of 2.5 nm±20%, the molybdenum layer has a thickness of 30 nm±20%, and the third TiN layer has a thickness of 50 nm±20%.

8. The method of claim 1, wherein the first or second source/drain region is a doped region in the first or second silicon substrate.

9. The method of claim 1, wherein the annealing process comprises annealing the first or second source/drain region on the first or second silicon substrate at 900° C.±20% for 5 seconds±20% to activate the P-type dopant or the B-dopant in the first or second source/drain region.

10. A ferroelectric neural network cell, comprising:
an N-type FeFET comprising: a first silicon substrate; a first gate stack disposed above the first silicon substrate, the first gate stack comprising an interfacial layer, a first HZO structure disposed above the interfacial layer, and a first TiN layer disposed above the first HZO structure; and a first source/drain region located proximate to each of two sides of the first gate stack, wherein the N-type FeFET is a FeFET having undergone H₂ plasma treatment (HPT); and
a P-type FeFET comprising: a second silicon substrate; a second gate stack disposed above the second silicon substrate, the second gate stack comprising a second HZO structure, a second TiN layer disposed above the second HZO structure, a molybdenum layer disposed above the second TiN layer, and a third TiN layer disposed above the molybdenum layer; and a second source/drain region located proximate to each of two sides of the second gate stack, wherein source regions of the N-type FeFET and the P-type FeFET are coupled to a matching line (ML), and drain regions of the N-type FeFET and the P-type FeFET are coupled to a ground end.

11. The ferroelectric neural network cell of claim 10, wherein the interfacial layer is aluminum oxide with a thickness of 1 nm±20%.

12. The ferroelectric neural network cell of claim 10, wherein the first and second HZO structures are formed to take on a total thickness of 9 nm±20% by cyclically stacking 7 Å HfO₂ and 7 Å ZrO₂.

13. The ferroelectric neural network cell of claim 10, wherein the first TiN layer has a thickness of 50 nm±20%, the second TiN layer has a thickness of 2.5 nm±20%, the molybdenum layer has a thickness of 30 nm±20%, and the third TiN layer has a thickness of 50 nm±20%.

14. The ferroelectric neural network cell of claim 10, wherein the first source/drain region is a P-type doped region in the first silicon substrate, and the second source/drain region is a B-type doped region in the second silicon substrate.
